(19) United States
(12) Patent Application Publication
(10) Pub. No.: US 2026/0128522 A1
(43) Pub. Date: May 7, 2026

(54) ELECTRONIC DEVICE

(71) Applicant: Orica International Pte Ltd, Singapore (SG)

(72) Inventors: Kresten Lukas Coffey NIELSEN, Hamilton (AU); Kieren Peter RASMUSSEN, Sydney (AU); Johann ZANK, Sydney (AU)

(21) Appl. No.: 19/118,956

(22) PCT Filed: Oct. 6, 2023
(86) PCT No.: PCT/SG2023/050678

§ 371 Date: Apr. 7, 2025

(30) Foreign Application Priority Data
Oct. 7, 2022 (AU) 2022902919
Mar. 7, 2023 (AU) 2023900616

(51) Int. Cl. H01Q 7/06; G01R 33/00; G01R 33/02

(52) U.S. Cl. CPC H01Q 7/06; G01R 33/0011; G01R 33/02

(57) ABSTRACT

Described herein is an electronic device having an antenna that detects or generates a magnetic field, the antenna defining a cavity within which is located at least part of one or more electronic components, wherein within the cavity and in between the antenna and the at least part of the one or more electronic components is located a magnetic field permeable composite, the magnetic field permeable composite comprising a binder material and particulate magnetisable material.

### FIELD OF THE INVENTION

The present invention relates in general to electronic devices and in particular to electronic devices that have an antenna that detects or generates a magnetic field.

### BACKGROUND OF THE INVENTION

Many electronic devices make use of an antenna for receiving and/or sending a signal. The antennas employed are often of a type that detect/generate a magnetic field and they are commonly present in the form of a coil structure. In addition to an antenna, such electronic devices will typically contain one or more other electronic components.

Key design features for consideration when developing such electronic devices include performance, efficiency, cost and physical form. As a general rule, it is desirable to design the electronic devices so as to have optimum performance and efficiency within as compact physical form as possible.

Coil based antenna systems typically present an internal cavity defined by the coil structure. To reduce the physical form of a given electronic device one option in theory is to locate one or more electronic components of the device partially or fully within the cavity defined by the coil structure. However, in practice doing so presents a number of disadvantages.

For example, magnetic flux associated with the magnetic field generated by the antenna will interact with an electronic component located within the cavity defined by the coil structure and generate eddy currents. The so formed eddy currents can generate resistive losses that transform at least some of the energy input into heat. The net result of that resistive effect reduces the device performance in terms of magnetic field strength at a point away from the device, and power efficiency. The eddy currents also increase the impedance of the antenna, so that a larger driving voltage is required to produce the same current in the antenna coil. In a lumped-element model of the antenna circuit, the additional impedance appears as a so-called “external resistance”. This external resistance is equivalent to an additional resistance in series with the antenna circuit.

In a similar way, magnetic flux associated with an external magnetic field detected by the device will interact with an electronic component located within the cavity defined by the coil structure and generate eddy currents. These eddy currents create their own magnetic field, which acts to oppose the externally applied field and reduce the signal appearing at the device's receiver. If the device coil is in a resonant tuned configuration, the external resistance decreases the quality factor (Q factor) of the antenna circuit. This reduces the “resonant step-up” in the antenna and hence the voltage at the device's receiver is lower. Addition of a magnetisable filler also has the well-known benefit of concentrating the flux associated with the external magnetic field such that there is a greater magnetic flux density within the antenna coil.

To avoid such reductions in performance and efficiency, such electronic devices are commonly designed to minimise the formation of such eddy currents by locating eddy current causing electronic components outside of the cavity defined by the coil and suitably distant at least from the most intense part of the magnetic field. In other words, optimising the physical form of the device is typically sacrificed in preference to maintaining acceptable performance and efficiency.

An opportunity therefore remains to rethink the design principles of electronic devices having antennas that detect or generate a magnetic field to enable greater flexibility in optimising the physical form of the device while still maintaining acceptable performance, cost and efficiency.

### SUMMARY OF THE INVENTION

The present invention provides an electronic device having an antenna that detects or generates a magnetic field, the antenna defining a cavity within which is located at least part of one or more electronic components, wherein within the cavity and in between the antenna and the at least part of the one or more electronic components is located a magnetic field permeable composite, the magnetic field permeable composite comprising a binder material and particulate magnetisable material.

The present invention also provides a method of producing an electronic device having an antenna that detects or generates a magnetic field, the antenna defining a cavity within which is located at least part of one or more electronic components, the method comprising locating within the cavity and in between the antenna and the at least part of the one or more electronic components a magnetic field permeable composite, the magnetic field permeable composite comprising a binder material and particulate magnetisable material.

The present invention further provides a method of improving antenna signal detection or output performance of an electronic device having an antenna that detects or generates a magnetic field, the antenna defining a cavity within which is located at least part of one or more electronic components, the method comprising locating within the cavity and in between the antenna and the at least part of the one or more electronic components a magnetic field permeable composite, the magnetic field permeable composite comprising a binder material and particulate magnetisable material, wherein the improved signal detection or output is that relative to the same electronic device absent the magnetic field permeable composite.

In the context of signal detection, an electronic device in accordance with the invention can advantageously exhibit higher (improved) received signal voltage relative to the same electronic device absent the magnetic field permeable composite upon being exposed to the same level of externally generated/applied magnetic field.

In the context of signal output, an electronic device in accordance with the invention can advantageously exhibit higher (improved) signal output performance using less or equal input power relative that input power being applied to the same electronic device absent the magnetic field permeable composite.

It has now been found possible to produce an electronic device in which one or more electronic components are partially or fully located within a cavity defined by an antenna that detects or generates a magnetic field without adversely affecting the antenna performance or efficiency.

Without wishing to be limited by theory, it is believed positioning the magnetic field permeable composite within the cavity in between the antenna and the at least part of the one or more electronic components preferentially funnels lines of magnetic flux (associated with the magnetic field detected or generated by the antenna) away from the at least part of the one or more electronic components located in the cavity, thereby minimising or avoiding the formation of adverse eddy current interactions between internal magnetic flux lines (associated with the magnetic field detected or generated by the antenna) and those electronic components.

Offering both improved antenna signal performance and an ability to design the electronic device with one or more electronic components partially or fully contained within the cavity defined by the antenna, electronic devices in accordance with the invention offer many practical advantages over their conventional counterparts. For example, the devices that generate a magnetic field can operate with lower power input while providing the same signal performance, or alternatively operate with the same power input while providing improved signal performance. The devices that detect a magnetic field are more sensitive to detecting that magnetic field. The size of the devices can also be decreased, which in turn derives many other benefits such as reducing cost and offering shaped configurations not previously viable.

The magnetic field permeable composite located within the cavity of the antenna also significantly improves the durability of the electronic device making it particularly well-suited for use in mining, quarrying, construction, tunnelling, geotechnical monitoring and engineering operations where the device is often subject to harsh environments, for example being exposed to an explosive shock wave and/or heavy earthmoving equipment.

Further aspects, embodiments and/or advantages of the invention are discussed in more detail below.

### BRIEF DESCRIPTION OF DRAWINGS

The present invention will herein be described with reference to the following non-limiting drawings in which:

In FIGS. 1 and 2 the line arrows indicate lines of magnetic flux. Those lines of magnetic flux are a way of visually representing the shape of the vector field of the magnetic flux density (which is usually given the symbol B in the art, and has units of tesla). In this specification, the phrase “detects or generates a magnetic field” refers to (i) the detection of a magnetic field generated remote from the device (i.e. an externally generated magnetic field), or (ii) the intentional generation of a magnetic field by the antenna of the device which is detectable at a position outside of and remote from the device (i.e. a magnetic field generated by the antenna). Away from the device and in free space, the magnetic flux density B vector field is simply proportional to the magnetic field strength H vector field. It will be appreciated by those skilled in the art that references in the art to “magnetic field” in free space can refer to either the B-field or the H-field. It will be appreciated by those skilled in the art that the paths of the flux lines are qualitatively similar within the device for transmit as well as receive. The intensity of the flux lines will be different in the two applications, as will the paths of the flux lines outside of the device. For simplicity, only the flux lines within the device are shown in FIGS. 1 and 2. The paths and intensity of the flux lines in those Figures are to be taken as qualitative only, and hence representative of the invention in both signal detect and output modes (i.e. receive and transmit, respectively).

FIG. 1 illustrates a comparative electronic device comprising an antenna that detects and/or generates a magnetic field (e.g., which detects a magnetic field at one or more times, and/or which generates a magnetic field at one or more other times). The antenna has located within its cavity an electronic component that interacts with the internal lines of magnetic flux associated the detected or generated field and results in the formation of eddy currents. Those eddy currents in turn generate resistive losses that transform at least some of the energy input into heat. The eddy currents also create their own magnetic field, which acts to oppose the intended detected or generated field (i.e. subtracts from it).

FIG. 2 illustrates an electronic device in accordance with the invention comprising an antenna that detects and/or generates a magnetic field. The antenna has located within its cavity an electronic component. Located between the antenna and the electronic component is a magnetic field permeable composite that preferentially directs the internal magnetic flux lines associated with the detected or generated field away from the electronic component thereby reducing or avoiding the formation of eddy currents.

FIG. 3 illustrates test data from Example 3 where deformation of electronic devices according to the present invitation and comparative devices were assessed as a function impact energy.

### DETAILED DESCRIPTION OF THE INVENTION

The present invention relates to electronic devices having an antenna that detects or generates a magnetic field.

By being an “electronic device” is meant the device comprises electronic componentry configured to operate one or more features of the device.

The electronic device has an antenna of the type that detects and/or generates a magnetic field. By having such an antenna it will be appreciated the electronic device is of a type that is capable of receiving and/or transmitting a signal. The signal may be analog or digital and its function will depend on the type and application of the device. The signal may include a magnetic induction (MI) signal, which may be a through-the-earth (TTE) MI signal with a modulation frequency/power selected to be used for TTE communication. The MI signal, in contrast to other forms of communication or signals based upon modulation of an electric field, may allow for improved TTE communication, including in a near field/zone or transitional field/zone, in contrast to the far field (or propagating wave field). The signal can encode or represent data and commands as using in commercial blasting applications, including an ARM command and/or a FIRE command, and data transmitted to and from the electronic device, as known in the field of commercial blasting.

As already noted, in this specification, the phrase “detects or generates a magnetic field” refers to (i) the detection of a magnetic field generated remote from the device, or (ii) the intentional generation of a magnetic field by the antenna of the device which is detectable at a position outside of and remote from the device.

Those skilled in the art will be familiar with antennas of the type that detect and generate a magnetic field. Further detail in relation to the antenna is discussed below.

Provided the electronic device has an antenna as described herein there is no particular limitation on the form the electronic device may take.

Due to the presence of the magnetic field permeable composite the electronic devices in accordance with the invention have been found to be particularly well suited for use in mining, quarrying, construction, tunnelling, geotechnical monitoring and engineering operations.

In one embodiment, the electronic device is for use in one or more of mining, quarrying, construction, tunnelling, geotechnical monitoring and engineering operations.

The magnetic field permeable composite located within the cavity defined by the antenna has been found to impart excellent durability to the electronic device. Electronic devices used in mining, quarrying, construction, tunnelling, geotechnical monitoring and engineering operations are often subjected to harsh environments. For example, such operations may expose electronic devices to strong vibrations or explosive shock waves (which can impose a very significant or large dynamic load on electronic devices), and/or industrial machinery such as heavy earth moving equipment. Conventional electronic devices are often quite fragile and can be quite easily damaged and as a result become unreliable/faulty/inoperable. The magnetic field permeable composite used in accordance with the invention has advantageously been found to enhance durability of the electronic device and assist with maintaining the electronic device in good operating condition upon it being exposed to harsh industrial environments.

In a further embodiment, the electronic device is selected from an explosives initiator, a monitor/sensor device, a communications device and combinations thereof. The electronic device is configured to use, and uses, the antenna for receiving and/or transmitting the signal.

Examples of suitable monitor devices include, but are not limited to, those for monitoring/sensing (including changes in) location, orientation, temperature, pressure, magnetic field, and combinations thereof.

Examples of suitable monitor devices also include those for tracking an ore body or parts thereof through a mining operation.

In one embodiment, the electronic device is in the form of a blast movement monitor.

In another embodiment, the electronic device is in the form of an ore body tracking monitor.

Examples of suitable communications devices include the aforementioned monitor/sensing devices and also devices for receiving, transmitting and/or relaying voice, text or other forms of data, including using the at least one MI signal described hereinbefore.

In the form of an explosives initiator the electronic device will be capable of receiving or producing an electronic signal (e.g., receiving an MI signal and decoding the MI signal to thereby generate an electronic signal) to initiate detonation of an explosives material that forms part of the device. Such a device will generally comprise relevant electronic componentry together with one or more components, devices, and/or structures configured for initiating or detonating a suitable explosives material such as a primary, secondary and/or tertiary explosives material. The incoming electronic signal is intended to trigger detonation of the explosive material. The function of the explosives initiator is to trigger initiation or detonation of the explosives material, which in turn typically triggers or is expected to trigger successful detonation of a tertiary explosives material that may, for example, reside together with the initiator device within a borehole or blasthole. The tertiary explosives material in the borehole is typically provided in moderately large or large quantities (e.g., along the majority of the borehole's length, or filling the majority of the borehole's volume), and for that given borehole will generally be responsible for the main explosive force output of the blasting operation.

Primary, secondary and tertiary explosive materials are well known to those skilled in the art.

Examples of the primary explosives include, but are not limited to, lead azide, mercury fulminate, lead styphnate and diazodinitrophenol.

Examples of the secondary explosives include, but are not limited to, pentaerythritol tetranitrate (PETN) and 2, 4, 6-trinotrotoluene (TNT).

Examples of the tertiary explosives include, but are not limited to, ammonium nitrate-based systems such as ammonium nitrate/fuel oil (ANFO) and ammonium nitrate emulsions and water gels.

While electronic explosives initiators will ultimately be destroyed in an explosion they initiate, such devices are commonly used to initiate a sequenced series of explosive events in which a blast wave, part of which constitutes a shockwave, propagating from an explosion initiated earlier in the sequence reaches the location of an initiator that has yet to electronically initiate its explosion within the sequence or be electronically signalled to initiate its explosion within another loaded sequence in the area (e.g., while a yet-to-be activated initiator is “slept” in the borehole or blasthole in which it resides). Similarly, electronic blast movement monitors are intended to endure/survive the blasting operations to track movement of blasted material in the mine site after the blasting operation has been completed.

It is therefore important such electronic devices remain functional upon being subjected to a shockwave generated remote from the devices during a blasting operation (e.g., one or more shockwaves generated by way of the detonation of explosive materials in boreholes remote from the borehole(s) or blasthole(s) in which particular electronic devices reside, and which can impose a dynamic shock on the particular electronic devices in association with shock wave propagation through a rock formation).

Electronic components of electronic devices are known to be adversely affected upon being subjected to a shockwave generated during the blasting operation. For example, electronic devices exposed to so-called “shock-stop” (i.e., the harsh conditions produced by a shockwave) can undergo partial or total failure. As those skilled in the art will appreciate, any type of malfunction of electronic devices used in association with blasting operations can cause significant economic and/or safety concerns.

The magnetic field permeable composite used in accordance with the invention has advantageously been found to assist with shielding electronic components within the electronic device from the adverse effects of an explosive shock wave.

In one embodiment, the electronic device in accordance with the invention is an electronic device for use within an explosive shock wave zone.

Those skilled in the art will appreciate that an explosive shock wave zone is an area (i) surrounding a point at which in explosive material is detonated, and (ii) subjected to an explosive shock wave.

The electronic device in accordance with the invention will comprise appropriate electronic components so the device can perform its intended task(s). Such electronic components include, but are not limited to, one or more of resistors, diodes, transistors, capacitors, microprocessors, batteries, inductors, sensors, accelerometers, circuit boards, connectors and wires. Such electronic components may also include one or more of the following:
Varistors (MOV)
Chokes
Transient Voltage Suppressors (TVS)
Diodes (Pin, Schottky, Zener, Silicon)
Bipolar Junction Transistor (BJT)
Silicon Controller Rectifier (SCR)
Thyristor
Triac
Metal Oxide Semiconductor Field Effect Transistor (MOSFET)
Isolated Gate Bipolar Transistor (IGBT)
Hall Effect Sensor
Transformers
Coupled Inductor
Super Cap
Light Emitting Diode (LED)
Photodetector
Photodiode
Phototransistor
Laser Diode
Optical Isolator (Optocoupler)
Digital Logic Integrated Circuits
Operation Amplifiers
Controller
Oscillator (MEMS, Crystal, Voltage Controlled, Numerically Controlled)
Power Management Circuits
Driver
Transceiver
Amplifier (Operation, Variable Gain, Programmable Gain, Current Sense, Transimpedance, Instrumentation, Differential, Power)
Analog to Digital Converter (ADC)
Digital to Analog Converter (DAC)
Real Time Clock (RTC)
Phase Locked Loop (PLL)
Isolators
Level Shifters
Decoder/Demodulator
Encoder/Modulator
Mixer
Microprocessor
Microcontroller
Application Specific Integrated Circuit (ASIC)
Field Programmable Gate Array (FPGA)
Complex Programable Logic Device (CPLD)
System on Chip (SOC)
System on Module (SOM)
Multi Chip Module (MCM)
System in Package (SIP)
Single Board Computer (SBC)
Micro-Electromechanical System (MEMS)
Sensors
Transducers (Electronic Input or Output)
Filters (Electronic)
Modules (Power, RF)
Transceiver
Transmitter
Receiver
Read Only Memory (ROM)
Random Access Memory (SRAM, DRAM, FRAM, MRAM)
Non-volatile Memory (NVM)
FLASH (NOR or NAND)
Electronically Erasable Programmable Read Only Memory (EEPROM)
Buttons
Switches
Connectors
Circuit Boards
Wire/Cables/Bus Bar
Batteries
Test Points

In one embodiment, the electronic components include a combination of two or more of a battery, printed circuit board, power management circuit, microcontroller, coil driver, switch (e.g. MOSFET), demodulator, filter, capacitor, resistor, diode and sensor (e.g. MEMS, accelerometer).

The antenna employed in accordance with the present invention is a type that detects or generates a magnetic field. Such antennas are well known to those skilled in the art.

In one embodiment, the antenna both detects and generates a magnetic field.

In another embodiment, the antenna detects a magnetic field.

In a further embodiment, the antenna generates a magnetic field.

The antenna used in accordance with the invention defines a cavity. By antenna defining a cavity is meant the material from which the antenna is made forms a structure having an internal three dimensional hollow or void. In other words, the cavity has length, width and depth dimensions. For example, when in the form of a helical coil antenna that cavity will be defined by the helical coil structure itself and represent the internal void of the helical structure.

Those skilled in the art will appreciate there are a number of antenna designs that are based on a flat or essentially two-dimensional design, for example flat coil or spiral antennas. While such antennas may have a central region that is absent of the antenna material, such flat antennas are not considered to define a true three-dimensional cavity in the sense that they do not have an appreciable depth dimension. Accordingly, antennas used in accordance with the present invention are not intended to embrace such two-dimensional or flat antenna designs. In other words, antennas used in accordance with the present invention do not include two-dimensional or flat antenna designs.

Notably, a cavity defined by the antenna used in accordance with the invention must have sufficient depth dimension to practically locate the one or more electronic components and also contain the magnetic field permeable composite.

Generally, the antenna will define a cavity having a depth of at least about 7 mm, or at least about 8 mm, or at least about 10 mm, or at least about 15 mm, or at least about 20 mm, or at least about 25 mm.

In one embodiment, the antenna will define a cavity having a depth ranging from about 7 mm to about 1000 mm, or from about 10 mm to about 500 mm, or from about 20 mm to about 500 mm, or from about 50 mm to about 250 mm.

From at least a design point of view, there has long been desire in the art to locate electronic components in the cavity defined by an antenna. However, to date any design advantages (for example size reduction) to be gained by doing so has been outweighed by the inherent reduction in performance of the electronic device due to adverse eddy current interactions between the internal magnetic flux lines associated with the magnetic field detected or generated by the antenna and the electronic components positioned within the cavity of the antenna.

A significant advantage afforded by the present invention is that the cavity defined by the antenna can partially or fully contain one or more electronic components of the electronic device without the performance of the electronic device being compromised.

It will therefore be appreciated the one or more electronic components that are located partially or fully within the cavity defined by the antenna in accordance with the invention are intended to of a type that upon being exposed to the internal (i.e. within the antenna cavity) magnetic flux lines associated with the magnetic field detected or generated by the antenna form eddy currents that generate resistive losses and transform at least some of the energy input into heat.

Those skilled in the art will appreciate the type and nature of electronic components that will be prone to the formation of eddy currents when located within the cavity of the antenna.

In one embodiment, the one or more electronic components are located wholly within the cavity.

In another embodiment, the one or more electronic components are located partially within the cavity.

In one embodiment, the at least part of the one or more electronic components occupies about 5 to about 80 volume %, or about 5 to about 60 volume %, or about 5 to about 50 volume %, or about 5 to about 40 volume %, of the cavity defined by the antenna.

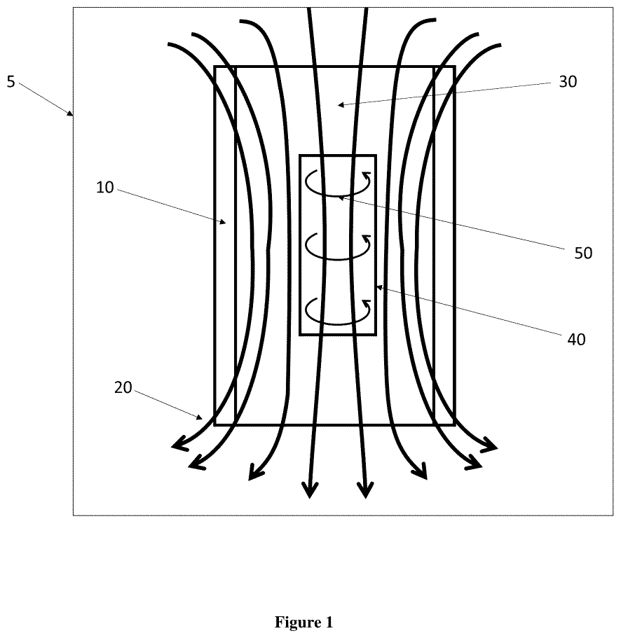

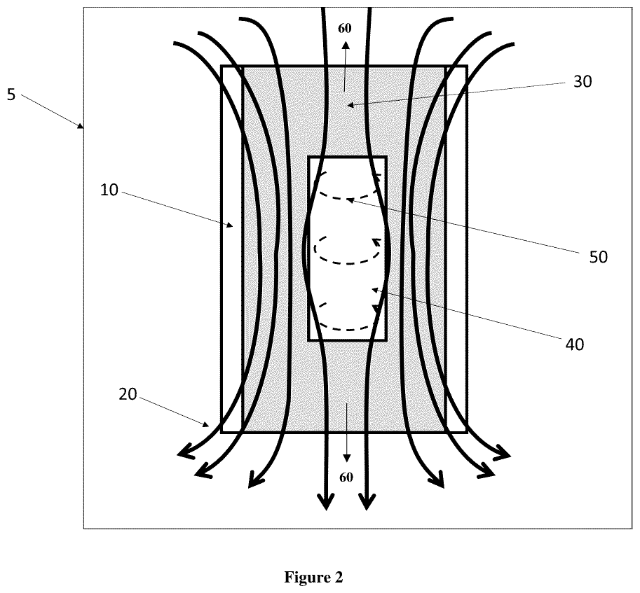

An electronic device in accordance with the invention has located within the cavity and in between the antenna and the at least part of the one or more electronic components a magnetic field permeable composite. To further describe features of the magnetic field permeable composite used in accordance with the invention reference is made to non-limiting FIGS. 1 and 2.

FIG. 1 schematically illustrates an electronic device (5) falling outside the scope of the present invention, the device (5) comprising an antenna (10) (represented as a cross-section thereof) that (i) detects or generates a magnetic field represented by magnetic flux lines (20), and (ii) has a circular helical structure (not shown) that defines a cavity (30). Within the cavity (30) is located an electronic component (40). The electronic component (40) interacts with magnetic flux lines (20) to form eddy currents (50) that generate resistive losses and transform at least some of the device (5) energy input into heat.

FIG. 2 schematically illustrates an electronic device (5) falling within the scope of the present invention, the device (5) comprising an antenna (10) (represented as a cross-section thereof) that (i) detects or generates a magnetic field represented by magnetic flux lines (20), and (ii) has a circular helical structure (not shown) that defines a cavity (30) filled with magnetic field permeable composite (shaded grey). Within the magnetic field permeable composite filled cavity (30) is located an electronic component (40). In contrast with the electronic device (5) shown in FIG. 1, the magnetic flux lines (20) preferentially flow through the magnetic field permeable composite filled cavity (30) and away from the electronic component (40) so as to minimise or avoid interaction with the electronic component (40) and consequently reduce or avoid the formation of eddy currents (50). Reducing or avoiding the formation of eddy currents (50) enables the device (5) to operate in (a) transmit mode with lower power input while providing the same signal performance, or alternatively operate with the same power input while providing improved signal performance, and (b) receive mode with a higher received signal voltage for the same externally generated/applied magnetic field. The magnetic field permeable composite (shaded grey) within the cavity (30) may extend outside the antenna in the axial direction (60) relative to the cavity (30).

In one embodiment, the antenna is a coil antenna.

Provided the antenna detects or generates the required magnetic field, there is no particular limitation on the material from which it may be constructed.

In one embodiment, the antenna is a conductive metal coil antenna and the conductive metal comprises copper, steel, aluminium, tin, nickel, silver, gold and combinations thereof.

The conductive metal may be coated with an insulation material such as a polymer or ceramic.

Provided the antenna detects or generates the required magnetic field, there is no particular limitation on the cross-sectional shape or so called turn shape the coil may have. For example, the antenna may be defined by a square, triangular, conical or circular coil cross-sectional shape.

Antennas defining a cavity having a circular coil cross-sectional shape are commonly known as a circular helical coil antennas.

In one embodiment, the antenna is a helical coil antenna.

A role or another role of the magnetic field permeable composite (for convenience also referred to herein as the “composite”) is to provide a medium through which internal (i.e. within the cavity of the antenna) magnetic flux lines associated with the magnetic field detected or generated by the antenna flows in preference to interacting with an electronic component located within the cavity defined by the antenna. Accordingly, the composite will be located within the cavity and in between the electronic component and the antenna. For optimum performance of the composite it will generally be placed adjacent and close to the electronic component. For example, the electronic component may be coated, encased or encapsulated in the composite. Alternatively, the magnetic field permeable composite may be provided with a preformed shape that enables the at least part of the one or more electronic components to be inserted therein. For example, the magnetic field permeable composite may itself be provided with a cavity within which is located the at least part of the one or more electronic components.

In one embodiment, the magnetic field permeable composite is positioned immediately adjacent the at least part of the one or more electronic components.

If desired or required the at least part of the one more electronic components located within the cavity may be covered or coated in a protective material that prevents it from coming into direct contact with the magnetic field permeable composite. That may, for example, be desired or required to where the magnetic field permeable composite is made of a material that could promote an adverse interaction with the at least part of the one or more electronic components.

As used herein, the expression “magnetic field permeable” composite is intended to mean a material having relative magnetic permeability (μᵣ) greater than unity. Equivalently, it means the material has magnetic permeability (μ) greater than the vacuum permeability (μ₀). As will be discussed in more detail below, the composite itself is a material made up of binder material and particulate magnetisable material. In the application of the electronic device in accordance with the invention of the composite presents as a solid material. While the binder that forms at least part of the composite matrix may not present magnetic properties per se, it is to be appreciated the entire solid mass of the composite (i.e. the binder material and particulate magnetisable material) is described herein as the “material” having the relative magnetic permeability (μᵣ) greater than unity.

In one embodiment, the magnetic field permeable composite coats or is in contact with the least part of the one or more electronic components located within the cavity.

In another embodiment, the magnetic field permeable composite encases the at least part of the one or more electronic components located within the cavity.

In a further embodiment, the magnetic field permeable composite encapsulates the at least part of the one or more electronic components located within the cavity.

It can often be convenient for the cavity to be substantially filled with the composite, with the one or more electronic components partially or fully embedded within the composite.

In one embodiment, the magnetic field permeable composite substantially fills the cavity and has the one or more electronic components partially or fully embedded within the composite.

In a further embodiment, the magnetic field permeable composite substantially fills the cavity and has all of the one or more electronic components encapsulated therein.

The cavity defined by the antenna will of course have a volume, at least part of which is occupied by the one or more electronic components. The remainder of the cavity volume not occupied by the one or more electronic components will for convenience be termed the “remaining volume” of the cavity. That remaining volume of the cavity will contain the magnetic field permeable composite and optionally one or more structural elements used in preparing the antenna (for example plastic structure used to support the coil windings).

Accordingly, the antenna may be described as defining a cavity having (i) a volume occupied by at least part of the one or more electronic components, and (ii) a remaining volume not occupied by the one or more electronic components, wherein within the remaining volume and in between the antenna and the at least part of the one or more electronic components is located a magnetic field permeable composite.

In one embodiment, the magnetic field permeable composite occupies at least 5 volume %, or at least 20 volume %, or at least 40 volume %, or at least 50 volume %, or at least 60 volume %, or at least 70 volume %, or at least 80 volume %, or at least 90 volume % of the remaining volume.

In a further embodiment, the magnetic field permeable composite occupies about 5 to about 100 volume %, or about 20 to about 100 volume %, or about 40 to about 100 volume %, or about 20 to about 80 volume %, or about 40 to about 75 volume % of the remaining volume.

The remaining volume may also comprise one or more structural elements. The structural element being part of the antenna that assists with supporting structural features of the antenna. For example, a coil antenna may be constructed using a structure such as a bobbin to support the coil windings. Such structural elements will often be made of plastic.

In a further embodiment, the structural element occupies about 0 to about 40 volume %, or about 0 to about 35 volume %, or about 5 to about 30 volume %, or about 10 to about 25 volume % of the remaining volume.

For avoidance of any doubt, the “remaining volume” is intended to mean the volume within the volume defined by the cavity that is (i) not occupied by the one or more electronic components, and (ii) located in between the antenna and the at least part of the one or more electronic components.

Also, by the “magnetic field permeable composite” occupying, is occupied by, or occupies that remaining volume is intended to mean that volume is occupied by composition per se that forms the composite (i.e. at least the binder material and particulate magnetisable material).

It is believed maximising the amount of composite within the cavity facilitates the preferential flow of internal magnetic flux lines through the composite and away from the one or more electronic components also located within the cavity.

The composite may also extend outside the cavity of the antenna. However, to maintain the function of the antenna those skilled in the art will appreciate the composite must be provided in a form that maintains an open magnetic circuit. In practice, that will generally mean that the composite might extend out from the cavity of the antenna in an axial direction relative to the cavity (see for example FIG. 2).

In one embodiment, the magnetic field permeable composite is located only within the cavity defined by the antenna. In other words, in one embodiment the magnetic field permeable composite is not located anywhere outside of the cavity defined by the antenna.

In a further embodiment, the magnetic field permeable composite further extends out from the antenna cavity in an axial direction (relative to the cavity).

The composite itself comprises a binder material and particulate magnetisable material.

A function of the binder material is to present together with the particulate magnetisable material a solid mass within the cavity of the antenna throughout which the particulate magnetisable material is distributed. In the application version of the electronic device the binder will therefore be solid. However, in producing the electronic device the binder may have a pourable or mouldable composition that subsequently cures or solidifies into the form of the composite present in the application form of the device.

The solid form of the composite may also have a solid gel-like character.

There is no particular limitation on the composition of the binder provided it can present in the electronic device as a solid mass having the particulate magnetisable material distributed therethrough.

The binder itself should of course be substantially non-conductive. Those skilled in the art will appreciate a conductive binder located within the cavity would be prone to generating eddy currents and thereby give rise to the problem with which the present invention is directed to addressing.

In one embodiment, the binder material comprises polymer, cement, plaster or bitumen.

Examples of suitable polymer binder materials include, but are not limited to, epoxy resin, polyester resin, polyurethane resin, silicone resin, polyolefin, polyamine and polyester.

As known to those skilled in the art, bitumen is a product derived from the petroleum industry often used in road construction. Bitumen is sometimes also referred to as asphalt. However, in some countries asphalt is described as the product derived from a combination of bitumen and aggregate such as sand, gravel and/or stone. In the context of the present invention reference to bitumen and is intended to mean the petroleum derived product absent aggregate.

In one embodiment, the binder material is cement.

Suitable cement products for use in accordance with the invention include both hydraulic and non-hydraulic cements.

Those skilled in the art will appreciate it there is a diverse range of cement products available commercially. Provided the cement product does not adversely interact with the electronic device and/or the magnetisable material, the present invention can advantageously make use of such commercially available cement products.

Examples of suitable cement products include, but are not limited to, Portland cement, Portland cement blends, pozzolan-lime cement, slag-lime cement, supersulfated cement, calcium sulfoaluminate cement, geopolymer cement and sorel cement.

The composite used in accordance with the invention includes the binder material as a binding matrix for the magnetisable material presented as a particulate matter distributed throughout the binder material. Accordingly, the magnetisable material is described as particulate magnetisable material.

There are a diverse range of particulate magnetisable materials commercially available that can advantageously be used in accordance with the invention.

Examples of suitable particulate magnetisable materials include, but are not limited to, iron, nickel, zinc, manganese, strontium, barium, chromium, cobalt, gadolinium, oxides or oxyhydroxides of any of the aforementioned, and mixtures or alloys of any of the aforementioned.

In one embodiment, the particulate magnetisable material comprises Fe₂O₃, Fe₃O₄, or a combination thereof.

In another embodiment, the particulate magnetisable material is a ferrite.

In a further embodiment, the ferrite comprises Fe₂O₃ blended with one or more elements selected from strontium, barium, manganese, nickel and zinc.

In yet a further embodiment, the particulate magnetisable material comprises manganese-zinc ferrite, nickel-zinc ferrite, or a combination thereof.

To afford the composite the magnetisable material will be provided in particulate form. Provided the magnetisable material can be suitably distributed throughout the binder material there is no particular limitation on the size or shape of the particulate magnetisable material.

The particulate magnetisable material, may for example, comprise particles having a number average dimension ranging from about 0.5 mm to about 20 mm, or from about 1 mm to about 10 mm.

In one embodiment, the particulate magnetisable material has a polydisperse particle size.

In a further embodiment, the particulate magnetisable material is anisotropic.

The particulate magnetisable material used in the composite in accordance with the invention provides a means to preferentially direct the internal magnetic flux lines associated with the magnetic field detected or generated by the antenna away from the one more electronic components position within the cavity of the antenna. Provided the composite performs that task, there is no particular limitation on the amount of particulate magnetisable material that can be combined with the binder material to produce the composite. The binder material will of course need to be present in an amount sufficient to bind the particulate magnetisable material into a solid mass.

In one embodiment, the composite comprises at least about 30 wt. % or at least about 40 wt. %, or at least about 50 wt. %, or at least about 60 wt. %, or at least about 70 wt. %, or at least about 80 wt. % particulate magnetisable material.

In a further embodiment, the composite comprises at least about 20 wt. %, or at least about 30 wt. %, or at least about 40 wt. %, or at least about 50 wt. %, or at least about 60 wt. %, or at least about 70 wt. % binder material.

One measure of the composite's ability to preferentially direct the internal magnetic flux lines associated with the magnetic filed detected or generated by the antenna away from the one or more electronic components is its relative magnetic permeability.

In one embodiment, the composite has a relative magnetic permeability of at least 2, or at least 5, or at least 10, at least 15, or at least 20, or at least 25, at least 30, or at least 35, at least 40, or at least 45, or at least 50.

As used herein the expression “relative magnetic permeability” is intended to mean the ratio of the material's magnetic permeability to the magnetic permeability of free space (i.e. the permeability constant). The relative magnetic permeability can be readily measured using a “B-H tester” and a toroid made from the composite. The composite is subjected to a magnetizing force, and a magnetic flux results within the toroid. The magnetizing force is created with one winding of wire on the toroid and another winding measures the flux created. The B-H test is performed for different field strengths. The resulting flux density B for different values of applied magnetic field H is be measured and plotted as a “B-H curve”. The slope of the B-H curve is the relative permeability (μᵣ). As the B-H curve is typically not a straight line, it's slope changes with applied H. So conventionally, relative permeability is taken to mean the “initial permeability” which is the relative permeability at small values of applied H (i.e. the slope at the start of the B-H curve).

Composite suitable for use in accordance with the invention is available commercially. For example, a product such as MC40™ (sold by Magment GmbH) that comprises a cement binder and particulate magnetisable material may be employed.

Provided its function of being magnetic field permeable is not adversely affected, the composite may comprise other constituent components.

For example, the binder matrix may comprise voids so as to present the composite in the form of a foam like product.

In one embodiment of the magnetic field permeable composite comprises voids. Such voids will typically be filled with a gas such as air.

To provide the composite with the required magnetic field permeability, those skilled in the art will appreciate the particulate magnetisable material will be presented within the composite such that it does not produce a conductive network of magnetisable material. For example, the particulate magnetisable material will generally not be used at a concentration that results in a substantive portion of the particles of magnetisable material being in contact with each other (i.e. the particles will be separated by at least a portion of the binder matrix). Having said that, a concentration of magnetisable material that results in physical contact of the particles may be used where the particles of magnetisable material are coated with and insulation layer that prevents a conductive network being formed even when the particles of magnetisable material are in contact with each other. A concentration of magnetisable material that results in physical contact of the particles may also be used where the particles of magnetisable material are not electrically conductive.

In addition to directing internal magnetic flux lines associates with the magnetic field detected or generated by the antenna away from the one or more electronic components located within the cavity of the antenna, the composite used in accordance with the invention can provide for numerous other advantages such as making the electronic device non-buoyant, provide a means for modifying the device thermal conductivity, assist with magnetic tracking and separation of the device from, for example, mined ore, and improve the overall durability of the device, particularly where the device is fully potted with the composite as herein described. In addition to providing for the improved antenna signal performance as described herein, the present invention advantageously enables that to be achieved in a manner that provides an opportunity for the unique redesign of the electronic device configurations. Notably, electronic devices in accordance with the invention can be produced with electronic components located within the cavity of the antenna without compromising signal performance. The size of the devices can therefore be decreased, which in turn derives many other benefits such as reducing cost and offering shape configurations not previously viable.

The present invention also provides a method of producing an electronic device having an antenna that detects or generates a magnetic field, the antenna defining a cavity within which is located at least part of one or more electronic components. That method is of course intended to produce electronic devices in accordance with the invention.

The method comprises locating within the cavity and in between the antenna and the at least part of the one or more electronic components the composite as described herein. As the role of the composite is to preferentially direct the magnetic flux lines associated with the magnetic field detected or generated by the antenna away from the one or more electronic components, it will generally be immediately adjacent or in contact with at least the part(s) of the one or more electronic components within the cavity defined by the antenna. It will generally be convenient for the composite to fill the entire cavity section that remains not taken up by the one or more electronic components (i.e. the “remaining volume” as described herein).

There is no particular limitation on the means by which the composite can be located within the cavity defined by the antenna. For example, if the composite is provided in a mouldable form it may be physically moulded into the cavity so as to position itself between the one or more electronic components and the cavity wall defined by the antenna. The composite may also be provided in the form of a pourable composition that cures or sets after being poured into the cavity.

The composite may therefore be described as being used as a potting material. Those skilled in the art will be familiar with so-called potted electronic devices.

While a function of composite is to direct internal magnetic flux associated with the magnetic field detected or generated by the antenna away from the one or more electronic components within the antenna cavity, provided an open magnetic circuit is maintained the composite may nevertheless extend outside the general area defined by the antenna and pot other regions of the electronic device. Where the composite extends out from the antenna it will of course be less important that it contain magnetisable material as the relevant electronic components are those that are at least in part located within the cavity of the antenna. Accordingly, composite that extends out from the antenna may be richer in binder material relative to the composite material located within the cavity of the antenna. Where composite does extend out from the antenna cavity it will generally do so in an axial direction relative to the cavity (see FIG. 2).

In one embodiment, only the binder component of the composite extends outside the cavity defined by the antenna.

A magnetic field generated by the antenna can advantageously be used to assist with positioning/aligning the magnetisable fraction of the composite within the cavity of the antenna. For example, where the composite is in the form of a flowable composition it can be poured into the cavity. Before the composite cures or sets and remains flowable, the antenna can be used to generate a magnetic field and thereby attract and/or align within the cavity the particulate magnetisable material. The magnetic field can be held until the composite cures or sets thereby locking in the alignment and location of the particulate magnetisable material. It will be appreciated alignment of the particulate magnetisable material within the cavity will be relevant when anisotropic magnetisable material is employed.

In one embodiment, locating the composite within the cavity comprises using a pourable form of the composite that cures within the cavity to form a solid mass.

In one embodiment, upon locating the magnetic field permeable composite in the cavity the antenna is used to generate a magnetic field to promote positioning and/or alignment of the particulate magnetisable material within the binder material located in the cavity.

The present invention also provides a method of improving antenna signal performance of an electronic device having an antenna that detects or generates a magnetic field, the antenna defining a cavity within which is located at least part of one or more electronic components as described herein. The method comprises locating within the cavity and in between the antenna and the at least part of the one or more electronic components a magnetic field permeable composite as described herein.

The improved antenna signal performance can advantageously be achieved using less or equal input power applied to the same electronic device absent the magnetic field permeable composite. Alternatively, the present invention enables the device to be operated with the same power input while providing improved signal performance.

Use of the composite in accordance with the invention increases the total flux produced for a given magnetizing force. That in turn results in more signal (magnetic flux density B) at the receiver for the same amount of electrical power dissipated in the transmitter.

Use of the composite in accordance with the invention also helps to reduce losses. Eddy current losses are equivalent to adding an extra ohmic resistance in series with the coil antenna. That is often referred to as the external resistance. It reduces the amount of current that the batteries can drive through the antenna, and hence the amount of signal produced. By using the composite the external resistance is reduced. That works by providing a path for the flux lines that has higher permeability (than air or other materials), so that they pass preferentially away from the electronic components.

The composite used in accordance with the invention can also act as a magnetic flux concentrator. When placed in an externally applied magnetic field, the magnetic flux through the antenna coil is higher than it would be in the absence of the composite. That can result in an improved signal to noise ratio (and hence measurement/communications performance).

The composite used in accordance with the invention may also help to shield a device from its own electrical noise. Electronic components that make up the device create small magnetic fields which may be picked up by the antenna. The composite may help contain them within the antenna cavity such that they do not interact with the antenna per se.

The present invention will herein be described with reference to the following non-limiting examples.

### EXAMPLES

### Example 1

To demonstrate the advantages of using the magnetic field permeable composite in a device that generates a magnetic field, a representative model device was made. The model device consisted of a helical coil antenna with an internal cavity defined by the coil antenna. The cavity could contain the magnetisable composite or be left empty. Within the cavity there was also a pocket into which model electronic components could be placed, or left empty. Thus, the model devices are represented schematically by FIGS. 1 and 2. The properties of the helical coil antenna are shown in Table 1.

TABLE 1

| | | |
|---|---|---|
| Diameter | 70 | mm |
| Length of helical coil antenna | 60 | mm |
| Length of cavity | 60 | mm |
| Length of pocket | 60 | mm |
| Turns | 100 | |
| Wire Diameter | 0.5 | mm |
| DC Resistance, R_{DC} | 1.93 | Ω |
| Inductance with Air Core | 553.1 | μH |
| Inductance with Magment MC40 Core | 1329 | μH |
| Inductance with Epoxy/Ferrite | 1246 | μH |
| Composite | | |
| Tuning Capacitor | 100 | nF |
| Volume of cavity defined by antenna | 10.2 | % vol |
| occupied by electronic component(s) | | |
| Volume of cavity defined by antenna | 50.7 | % vol |
| occupied by magnetic field permeable | | |
| composite | | |
| Volume of cavity defined by antenna | 23.3 | % vol |
| occupied by other structural elements | | |
| Volume of cavity defined by antenna | 15.8 | % vol |
| that remains unoccupied | | |
| Volume Enclosed by Coil/antenna | 230907 | mm³ |

The experimental measurements were conducted in six configurations. First, the three different core options were tested without any electronic components within the cavity. Then the experiments were repeated after adding batteries to the internal cavity. The batteries are a model for ‘electronic components’ in general. Experience has shown that batteries can be particularly challenging with regard to the adverse eddy current effects relevant to the present invention. The three core options are shown in Table 2.

TABLE 2

| Core Option Name: | Ingredients: | Mass (gram): |
|---|---|---|
| Air Core (none) | none | none |
| MC40 | MC40 magnetisable concrete from Magment GmbH | 402.4 (total) |
| | Portland Cement | <=40 |
| | Ferrite Grains | 302-382 |
| | Other non-magnetisable fill | remainder |
| Epoxy Composite | Luci Clear Casting Resin from Bote-Cote, and | 57 |
| | Ferrite grains | 281 |

The MC40 composite was a commercially available cement/ferrite blend from Magment GmbH. The epoxy composite was prepared specially for this example, to demonstrate that many kinds of binder will be suitable. The binder was a commercial epoxy resin, while the ferrite grains were taken from MC40 material by screening. This ferrite was used for the sake of comparison with the MC40 option. The screened ferrite grains were of irregular shape and sizes of about 2 to 8 mm. The fine ferrite powder present in the MC40 material was not used in the epoxy composite. The maximum packing fraction of ferrite was used in the epoxy composite, resulting in 83% by mass of ferrite in the epoxy composite.

The different coil options were connected in series to a tuning capacitor and driven at their resonant frequency, which was similar for each configuration. The driving voltage and resulting current were measured. Results are shown in Table 3.

TABLE 3

| | | | Air | | Epoxy |
|---|---|---|---|---|---|
| | Measurement: | Unit: | Core: | MC40: | Composite: |
| | Frequency | Hz | 21290 | 13710 | 14203 |
| Without | Driving Voltage (RMS) | V | 0.5024 | 0.5296 | 0.5383 |
| Electronics | Current (RMS) | A | 0.25 | 0.25 | 0.25 |
| | Total Resistance | Ω | 2.01 | 2.12 | 2.15 |
| With | Driving Voltage (RMS) | V | 0.4987 | 0.5261 | 0.5345 |
| Electronics | Current (RMS) | A | 0.0798 | 0.2171 | 0.2077 |
| | Total Resistance, Rₜₒₜ | Ω | 6.25 | 2.42 | 2.57 |
| Change | External Resistance, Rₑₓₜ | Ω | 4.24 | 0.30 | 0.42 |
| | External Resistance/DC Resistance | % | 220% | 16% | 22% |
| | External Resistance/Total | % | 211% | 14% | 20% |
| | Resistance without electronics | | | | |

From Ohm's Law, the total resistance is simply equal to the driving voltage divided by the resulting current.

In Table 3 the change in resistance when the electronics components are added, is the ‘external resistance’ due to the electronics. That has been expressed in ohms and as a percentage of the resistance without electronics. From Table 3 it will be apparent that the penalty for adding electronics within the cavity of the coil antenna (the external resistance) is greatly reduced by using the magnetic field permeable composite in accordance with the invention.

### Example 2

To demonstrate the advantages of using the magnetic field permeable composite in a device that detects a magnetic field, the same model device configurations (from Example 1, with a tuning capacitor) were used. This time, the coil voltage was measured, when the device was subjected to an externally applied magnetic field. The magnitude of the external magnetic field was constant for all of the configurations tested. In each case, the frequency of the external field was adjusted to the resonant frequency of the device configuration under test.

In addition to the above, the six device configurations were also tested without the tuning capacitor, such that only the open circuit coil voltage was measured. Measuring both tuned and untuned configurations like this allows for the resistance of the antenna circuit when detecting an externally applied magnetic field to be measured.

The quality factor Q for a simple series tuned resonant circuit is simply the resonant coil voltage divided by the open circuit voltage. Where the open circuit voltage was measured at a slightly different frequency, it was adjusted to the resonant frequency using the known relationship from Faraday's law (V∝f). Once Q is known, the total resistance may be calculated:

$${R}_{tot} = \frac{2 π f L}{Q}$$

where L is the measured inductance for the configuration. Results are shown in Table 4.

TABLE 4

| | | | Untuned | | | Tuned | | |
|---|---|---|---|---|---|---|---|---|
| | Measurement: | Unit: | Air | MC40 | Epoxy | Air | MC40 | Epoxy |
| Without | Frequency | Hz | 21360 | 13712 | 14220 | 21360 | 13712 | 14220 |
| Electronics | Detected V | V | 0.8341 | 1.399 | 1.343 | 31.08 | 68.98 | 65.34 |
| | (RMS) | | | | | | | |
| | Q | | — | — | — | 37.3 | 49.3 | 48.7 |
| | Rₜₒₜ | | — | — | — | 1.99 | 2.32 | 2.29 |
| With | Frequency | Hz | 21360 | 13712 | 14220 | 21050 | 13697 | 14294 |
| Electronics | Detected V | V | 0.863 | 1.404 | 1.347 | 10.940 | 60.320 | 54.840 |
| | (RMS) | | | | | | | |
| | Q | | — | — | — | 12.9 | 43.0 | 40.5 |
| | Rₜₒₜ | Ω | — | — | — | 5.69 | 2.66 | 2.76 |
| [symbol] | Rₑₓₜ | Ω | — | — | — | 3.70 | 0.34 | 0.47 |
| | $\frac{{R}_{ext}}{{R}_{D C}}$ | % | — | — | — | 192% | 17% | 25% |
| | $\frac{{R}_{ext}}{{R}_{tot} ( no electr . )}$ | % | — | — | — | 186% | 15% | 21% |

[symbol]

indicates data missing or illegible when filed

The increase in total resistance by adding the electronics components is shown Table 4. The increase is much more severe when the magnetic field permeable composite is not present. It will be noted that the measured total resistance Rₜₒₜ and external resistance Rₑₓₜ are similar when measured with the device in a transmitter configuration (a device that generates a magnetic field, Table 3) or in a receiver configuration (a device that detects a magnetic field, Table 4). The small difference is due to the small difference in the path of the flux lines in the two use cases and experimental uncertainty. The examples nevertheless clearly demonstrate the benefit of the invention for detecting or generating a magnetic field.

### Example 3

To demonstrate the advantage of using a magnetic field permeable composite in a device that is intended to survive the blasting operation (to be resistant to earth movement, crushing, blast pressures, shock vibrations and “shock-stop”) model devices were subjected to an impact test. Devices with and without a composite filler were compared, to demonstrate the advantageous shielding of the electronic components from the damaging effects of the blast and earth movement.

An impact testing device was built, in which a striking head travelled on vertical rails to strike a model device on a fixed anvil. The striking head was constructed of rectangular steel bar, aligned with the device axis. The striking head was loaded with different masses for different tests. The striking head was raised to a variable height on the rails, before being released, and accelerating under gravity to strike the device under test. The initial height h and mass m were adjusted in different tests to give a desired kinetic energy E at impact, according to E=mgh. For each test, the impact event was recorded with a video camera. The maximum deformation (as a percentage of the initial device width) was measured by comparing frames of the video.

The model devices had an outer jacket constructed of polyethylene pressure pipe (PE100 Series One) with a nominal outer diameter of 90 mm and a wall thickness between 8.2 mm and 9.2 mm. The first kind (modelling a composite-filled device) contained a 3D-printed air-filled shell approximating the shape of a circuit board and batteries, embedded in high-strength concrete (to model the mechanical properties of a magnetisable filler). The second kind (modelling a device without composite filler) contained a close-fitting inner tube of a glass fibre-wound epoxy composite (FWC, inner diameter 5 mm and wall thickness 10 mm). There was no concrete inside this second kind of model device.

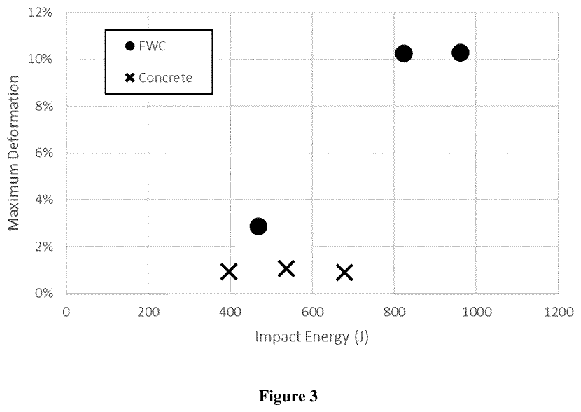

The results of the impact test are shown in FIG. 3. The deformation of the composite (concrete) filled model devices was very small. The 3D-printed shell embedded inside was later removed and found to be without apparent damage. However, the devices without concrete experienced much higher deformation. It should be noted that the sample at the highest impact energy (960 J) contained an additional nylon bobbin, which did not greatly affect the deformation.

Maximum deformation is taken to be a measure of damage potential during a blast event. This example clearly demonstrates the benefit of the invention for a device intended to survive blasting.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

1. An electronic device having an antenna that detects or generates a magnetic field, the antenna defining a cavity within which is located at least part of one or more electronic components, wherein within the cavity and in between the antenna and the at least part of the one or more electronic components is located a magnetic field permeable composite, the magnetic field permeable composite comprising a binder material and particulate magnetisable material.

2. The electronic device according to claim 1 for use in mining, quarrying, construction, tunnelling, geotechnical monitoring and engineering operations.

3. The electronic device according to claim 1 that is selected from an explosives initiator, a monitor device, a sensor device, a location device, a beacon, a tracking device, a communications device and combinations thereof.

4. The electronic device according to claim 1, wherein the antenna is a coil antenna.

5. The electronic device according to claim 4, wherein the coil antenna is a conductive metal coil antenna and the conductive metal comprises copper, steel, aluminium, tin, nickel, silver, gold and combinations thereof.

6. The electronic device according to claim 1, wherein the antenna is a helical coil antenna.

7. The electronic device according to claim 1, wherein the one or more electronic components are selected from resistors, diodes, transistors, capacitors, microprocessors, batteries, inductors, sensors, accelerometers, circuit boards, connectors and wires.

8. The electronic device according to claim 1, wherein the one or more electronic components are located wholly within the cavity.

9. The electronic device according to claim 1, wherein the one or more electronic components are located partly within the cavity.

10. The electronic device according to claim 1, wherein the magnetic field permeable composite encases the at least part of the one or more electronic components located within the cavity.

11. The electronic device according to claim 1, wherein the magnetic field permeable composite substantially fills the cavity and has the one or more electronic components partially of fully embedded therein.

12. The electronic device according to claim 1, wherein the magnetic field permeable composite substantially fills the cavity and has all of the one or more electronic components encapsulated therein.

13. The electronic device according to claim 1, wherein the binder material comprises polymer, cement, plaster or bitumen.

14. The electronic device according to claim 1, wherein the particulate magnetisable material is selected from iron, nickel, zinc, manganese, strontium, barium, chromium, cobalt, gadolinium, oxides or oxyhydroxides of any of the aforementioned, and mixtures or alloys of any of the aforementioned.

15. The electronic device according to claim 1, wherein the particulate magnetisable material is a ferrite.

16. The electronic device according to claim 1, wherein the particulate magnetisable material has a polydisperse particle size.

17. The electronic device according to claim 1, wherein the magnetic field permeable composite has a relative magnetic permeability of at least 2.

18. A method of producing an electronic device having an antenna that detects or generates a magnetic field, the antenna defining a cavity within which is located at least part of one or more electronic components, the method comprising locating within the cavity and in between the antenna and the at least part of the one or more electronic components a magnetic field permeable composite, the magnetic field permeable composite comprising a binder material and particulate magnetisable material.

19. The method according claim 18, wherein upon locating the magnetic field permeable composite in the cavity the antenna is used to generate a magnetic field to promote positioning and/or alignment of the particulate magnetisable material within the binder material located in the cavity.

20. A method of improving antenna signal detection or output performance of an electronic device having an antenna that detects or generates a magnetic field, the antenna defining a cavity within which is located at least part of one or more electronic components, the method comprising locating within the cavity and in between the antenna and the at least part of the one or more electronic components a magnetic field permeable composite, the magnetic field permeable composite comprising a binder material and particulate magnetisable material, wherein the improved signal detection or output is that relative to the same electronic device absent the magnetic field permeable composite
